(19) United States
(12) Patent Application Publication
(10) Pub. No.: US 2023/0359116 A1
(43) Pub. Date: Nov. 9, 2023

(54) SYSTEM AND PROCESS FOR CLEANING A MEMBRANE

(71) Applicant: Intel Corporation, Santa Clara, CA (US)

(72) Inventors: Safak SAYAN, San Jose, CA (US); Jae Young KANG, Campbell, CA (US); Abdolreza JAVADI, San Jose, CA (US); Srinath SATYANARAYANA, Folsom, CA (US); Herbert HSU, Mountain View, CA (US); Christopher KAPLAN, Oakland, CA (US)

(21) Appl. No.: 17/738,024

(22) Filed: May 6, 2022

(51) Int. Cl. G03F 1/64; H04R 1/02; B08B 7/02; B08B 11/02; B08B 13/00; G01N 29/12

(52) U.S. Cl. CPC G03F 1/64; H04R 1/028; B08B 7/026; B08B 11/02; B08B 13/00; G01N 29/12; G03F 1/22

(57) ABSTRACT

The present disclosure is directed to a membrane cleaning system and a membrane cleaning process, the membrane cleaning system including: a membrane; a membrane holder accommodating the membrane in a cut-out section within the membrane holder, wherein the cut-out section allows access to the membrane from two opposing sides; and a speaker configured to emit sound waves of a resonant frequency of the membrane for a predetermined duration and at a predetermined amplitude, wherein the sound waves are directed to one side of the membrane.

### BACKGROUND

A pellicle is a thin transparent membrane that protects a photomask during chip production flow. The pellicle is mounted on the photomask and prevents particles from falling on the photomask during the production process. Without a pellicle, a particle may land on a photomask causing a scanner during photolithography production steps to print repeating defects on the wafer, which would negatively impact the yield. Similarly, any particle that is present on the pellicle prior to and/or after mounting on the photomask may likewise cause a scanner during photolithography production steps to print repeating defects on the wafer, which would negatively impact the yield.

Accordingly, during a photolithography process, a major source of defects may be attributed to particles that are present on the pellicle. These defects are a major factor in reduced yields that may need to be addressed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 schematically shows the system for cleaning a membrane in a side view and in a horizontal orientation according to the present disclosure;

FIG. 2 schematically shows a membrane holder further including a membrane frame in a top view according to the present disclosure;

FIG. 3 schematically shows the system for cleaning a membrane including a laser Doppler vibrometer in a side view in one configuration according to the present disclosure;

FIG. 4 schematically shows the system for cleaning a membrane including a laser Doppler vibrometer in a side view in another configuration according to the present disclosure;

FIG. 5 schematically shows the system for cleaning a membrane including a computer with a non-transitory computer readable medium according to the present disclosure;

FIG. 6 schematically shows the system for cleaning a membrane in a side view and in a vertical orientation according to the present disclosure;

FIG. 7 schematically shows a simplified flow diagram for an exemplary process according to an aspect of the present disclosure; and

FIG. 8 shows a representative example of an identification of a resonant frequency according to an aspect of the present disclosure.

### DETAILED DESCRIPTION

In the semiconductor industry, a photolithography process refers to a process in which a pattern is delineated in a layer of material (e.g., photoresist) sensitive to photons, electrons or ions. The principle is similar to that of a photo-camera in which an object is imaged on a photo-sensitive emulsion film. While with a photo-camera the “final product” is the printed image, the image in the semiconductor process context typically is an intermediate pattern which defines regions where a material is deposited or removed.

A typical photolithography system includes a light source, optical system and a transparent photomask. The light source emits light through the optical system and photomask onto a photoresist layer of a semiconductor wafer. The photomask defines the “intermediate pattern” used for determining where photoresist is to be removed or left in place. A photomask typically is formed on a glass blank. The photomask and glass blank together are referred to as a reticle.

The photomask serves to define geometries for materials deposited or etched on the wafer or materials applied to the wafer. The patterned film on the reticle includes mask lines and line spacings of less than 10 micrometers (μm). Depending on the reduction factor x, line width and line space geometries for a resulting semiconductor device may range from less than 10 μm to less than 2 μm. When working with such small geometries, it is important that the reticle and other components in the fabrication processes are free of foreign particles, e.g., dust. A tiny speck of dust may alter the desired pattern to be imaged onto the wafer, which causes a defect that may drastically reduce the yield of the process. Conventionally, a thin transparent membrane, e.g., a pellicle, is applied over the photomask portion of the reticle to keep the photomask portion free of foreign particles. However, due to nature of the manufacturing process of the membranes, these membranes may themselves not always be particle-free, and these particles can drop on the reticle surface during usage and cause the before stated defect.

One previous attempt for solving this problem involved using a particle-free fabrication process of the membrane. However, such approach can be challenging and may not provide a solution for removing particles that are acquired after the membrane is sent from the supplier. Another previous attempt for solving this problem involved cleaning the membrane in a conventional manner. However, due to the fragile nature of the membrane, this may result in damaging the membrane. Specifically, the membrane may be damaged or destroyed during the course of using a cleaning process that involves contacting the membrane, such as cleaning the membrane using a solvent, or by treating the membrane with a gas, etc. If membrane is not cleaned, then the reticle needs to be fixed by removing the membrane from the reticle, cleaning the reticle surface and undergoing mask requalification (in other words, repeating the quality control of the mask). However, this may be very time consuming and costly.

To address the above insufficiency, the present disclosure provides a system for cleaning a membrane that is “contactless”. In other words, this system enables particle removal from two opposing sides of the membrane by employing a “contactless” cleaning process. For the contactless cleaning process, the system takes advantage of the natural frequencies (also referred to as eigen frequencies) of a membrane. More particular, the system utilizes the frequency at which a membrane tends to vibrate or oscillate in the absence of any driving or damping force, which is called the natural frequency. The motion pattern of a membrane oscillating at its natural frequency is called the normal mode (if all parts of the system move in a sine wave with that same frequency). If the oscillating membrane is driven by an external force at the frequency at which the amplitude of its motion is greatest (close to a natural frequency of the system), this frequency is called resonant frequency. In the present system, a speaker (e.g., audio speaker), as the external force, is used to generate sound waves in the frequency range of 1 Hz-2000 Hz. The natural vibration modes of the membrane couples and resonates at the natural frequencies, as a result, the membrane vibrates. This physical vibration results in particle detachment from membrane, thereby providing a contactless cleaning system.

Hence, unlike conventional cleaning systems, the present cleaning method avoids using a potentially challenging particle-free fabrication process of the membrane and avoids causing damage to the membrane. Moreover, advantageously, integration and implementation of this membrane cleaning method may significantly improve mask requalification frequency by reducing the number of membrane-induced defects. Reduction in mask inspection frequency at the wafer factories may result in capital savings and improve operational efficiency.

In one example, the benefits of the present system were demonstrated using commercially available EUV pellicles (e.g., Mk2.2. or Mk4) that were cleaned using the system of the present disclosure. The pellicles cleaned in accordance with the disclosure were mounted on photomasks for extra ultraviolet (EUV) photolithography and shipped to the wafer factories for the detection of defects. A three time's reduction in failure rate was observed for the pellicles that were cleaned in accordance with the present disclosure.

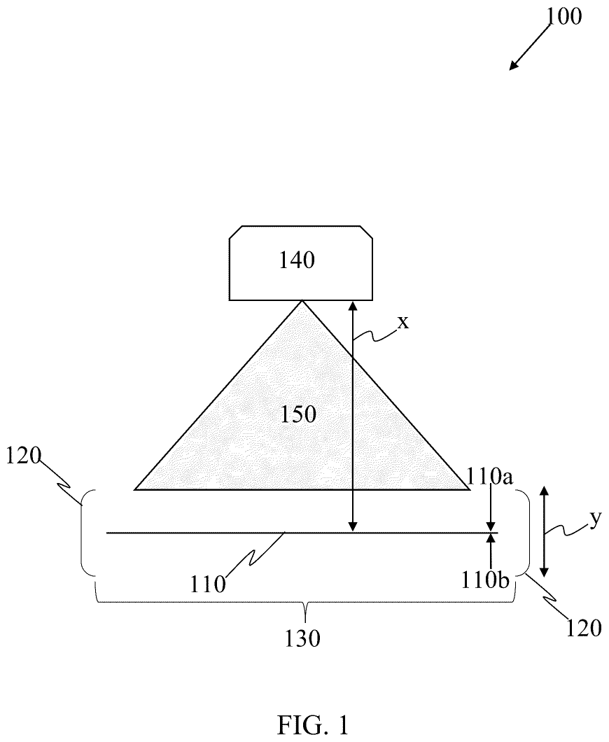

Accordingly, in a first aspect, as shown in FIG. 1, there is provided a system 100 for cleaning a membrane 110, the system 100 including the membrane 110. The system 100 may further include a membrane holder 120 accommodating the membrane 110 in a cut-out section 130 within the membrane holder 120, wherein the cut-out section 130 allows access to the membrane 110 from two opposing sides 110a, 110b. The system 100 may further include a speaker 140 configured to emit sound waves 150 of a resonant frequency of the membrane 110 for a predetermined duration and at a predetermined amplitude directed to one side of the membrane 110.

The membrane 110 may have the dimension of a layer or a sheet, indicating that the membrane 110 may typically extend into two directions (perpendicular to each other), while having a thickness in a direction that is perpendicular to the two directions in which the membrane 110 extends. The two surfaces that extend into the two directions are referred to herein as the opposing sides 110a, 110b. The distance between the opposing sides 110a, 110b may refer to the thickness of the membrane 110.

While the two surfaces of the membrane 110, when not exposed to sound emission, may form a substantially straight line, the sound emission may cause the membrane 110 to vibrate. This vibration may cause the membrane 110 to move in a sine wave with the same frequency of the sound emission, thereby causing a displacement of the membrane 110 from the previous substantially straight line.

While the present system 100 could be applied to any membrane, according to various aspects, it is advantageous to apply the system 100 to thin membranes, for example, to membranes that have a thickness of below 10 μm, or of below 5 μm, or of about or below 1 μm. Advantageously, at a thickness of about 1 μm or below, the displacement of the membrane due to sound emission is facilitated or increased, thereby resulting in a more effective ejection of particles from the membrane 110. In some aspects, the membrane may be a pellicle to be used in photolithography. In some aspects, the pellicle may have a thickness of below 500 nanometers (nm), or of below 400 nm, or the thickness of the pellicle may be in the range of about 10 nm to about 350 nm, or in the range of about 30 nm to about 100 nm. The pellicle of such low thickness may be used in EUV lithography. Advantageously, the system 100 may be particularly useful for pellicles in EUV lithography since other cleaning methods (such as cleaning methods that rely on contacting the pellicle) may damage the pellicle due to its fragile nature.

The two directions defining length and height of the two surfaces that form the two opposing sides 110a, 110b of the membrane 110 may be about 5 cm to about 20 cm, or about 10 cm to about 16 cm. The length and height may be the same (i.e. forming a square) or different. For example, the length may be in a range of about 15 cm to about 16 cm, while the height may in a range of about 12 cm to about 13 cm.

A material of the membrane 110 may include, but not limited to a polymer material. Advantageously, the displacement of the membrane 110 due to vibration may be facilitated by tuning into natural frequency of the membrane regardless of the nature of material.

The membrane holder 120 may be configured to accommodate the membrane 110. The membrane holder 120 may have the shape of a quadrangular frame, having a cut-out section 130. The cut-out section 130 may have a length that is about the same length as the membrane 110. Accordingly, the membrane 110 may be accessible (e.g., not covered by the membrane holder 120) on both opposing sides 110a, 110b. The membrane holder 120 may have a thickness y that is about 1 millimeter (mm) to about 10 centimeters (cm), or about 5 mm to about 5 cm, or about 10 mm to about 20 mm, or be about 18 mm.

The speaker 140 (e.g., an audio speaker) may emit sound waves 150 directed substantially at the membrane 110. The speaker 140 may thus include a tone generator that may be configured to emit sound waves 150 in the range of about 1 Hertz (Hz) to about 2000 Hz, or in the range of about 100 Hz to about 1000 Hz. The speaker 140 may be configured to receive instructions for emission of the sound waves 150 from a processor (not shown). The speaker 140 may be positioned to emit sound waves 150 to one of the two opposing sides 110a, 110b of the membrane 110.

According to some aspects, an arrangement between the speaker 140 and the membrane 110 may be such that the speaker 140 is on top of the membrane 110, i.e. such that emission of sound waves 150 is vertical in a downward direction. Between the membrane 110 and the speaker 140 may be a distance, defined as the distance x. According to various aspects, the distance x of the membrane 110 to the speaker 140 may be about 1 mm to about 20 cm, or about 5 mm to about 1 cm, or about 10 mm to about 5 cm, or about 1 mm to about 5 cm. Additionally or alternatively, the distance x of the membrane 110 to the speaker 140 may be less than 5 cm, or less than 3 cm, or less than 1 cm. Advantageously, at a distance of about 10 mm to about 20 mm, or at about 15 mm, the distance is such that a maximum ejection of particles is caused without causing any damage to the membrane 110. While the emission of sound waves in FIG. 1 is schematically shown as a triangle for illustrative purposes, it is understood that the actual emission of sound waves 150 may not occur within the geometric boundaries shown therein, but follows the well-known laws of acoustic sound propagation.

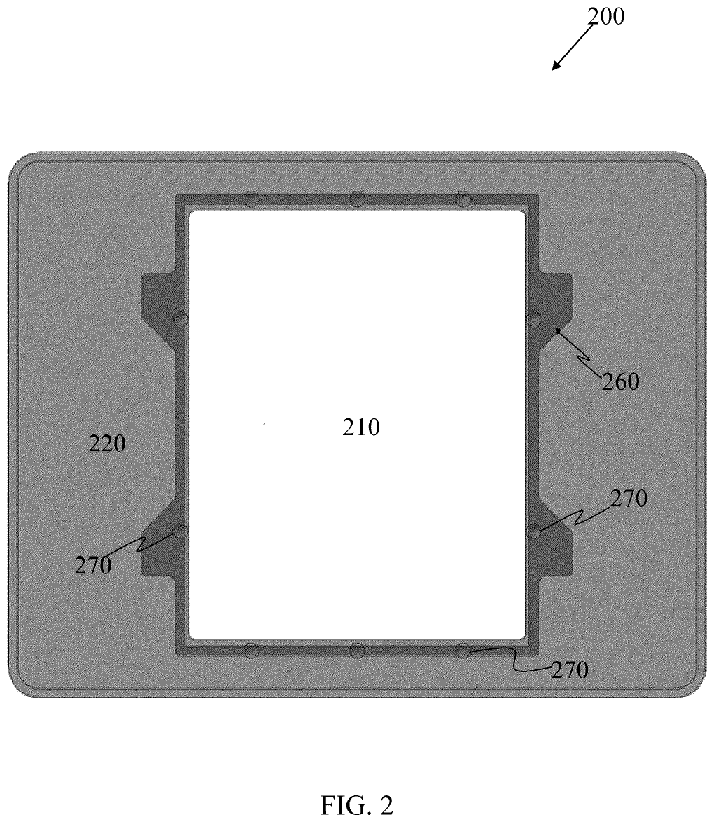

With reference to FIG. 2, the membrane 210 may be positioned (e.g., held) in a membrane frame 260, and assembled to the membrane frame 260 by assembling means 270. For example, the membrane 210 may be assembled in or on the membrane frame 260 by means of an adhesive, clamps, etc. Advantageously, by assembling the membrane 210 in a membrane frame 260, the membrane 210 may be transferred from a container (not shown) into the pellicle holder 220 with more ease. For example, the transfer of the membrane 210 from the container to the membrane holder 220 may be carried out by a robot arm (not shown). Similarly, after the cleaning process, the membrane frame 260 together with the membrane 210 may be removed from the membrane holder 220 more easily to proceed with a subsequent process step.

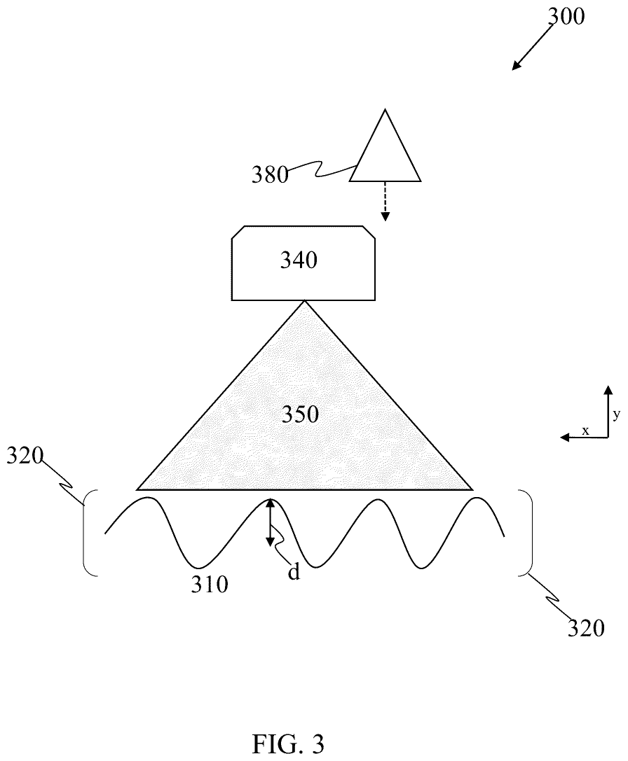

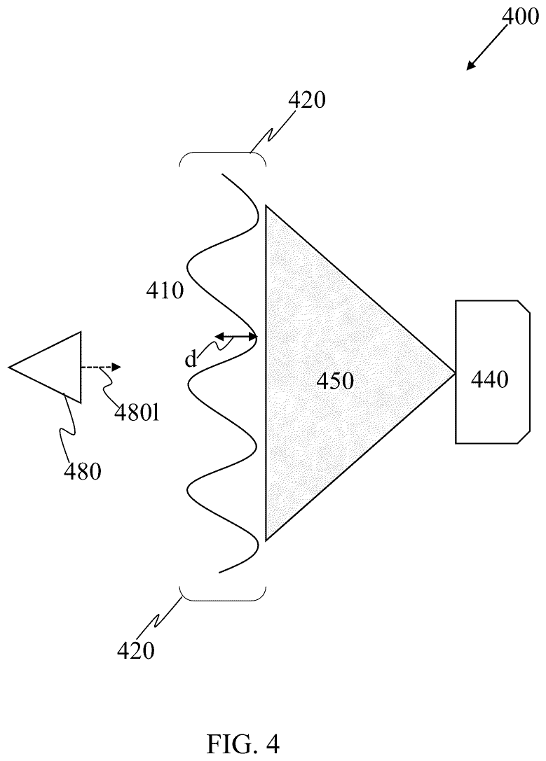

With reference to FIG. 3, according to various aspects, the system 300 may include a laser Doppler vibrometer 380 configured to measure the displacement d of the membrane 310 within the membrane holder 320 due to the emission of sound waves 350 from the speaker 340, i.e., the vibration measurement of the membrane surface. The function of the laser Doppler vibrometer 380 may be to identify a resonant frequency of the membrane 310 prior to the cleaning of the membrane 310. For example, each type of membrane 310 may have at least one individual resonant frequency, such as 1, 2, 3, or 4 resonant frequencies. In one aspects, the laser Doppler vibrometer 380 may be positioned on the same side of the speaker 340 and offset from an x-y plane in a direction z. In an alternative aspect, as shown in FIG. 4, the laser Doppler vibrometer 480 may be positioned on the opposite side of the speaker 440 and the sound emission 450 with a laser 4801 of the laser Doppler vibrometer 480 pointing perpendicular to the membrane 410 in the membrane holder 420.

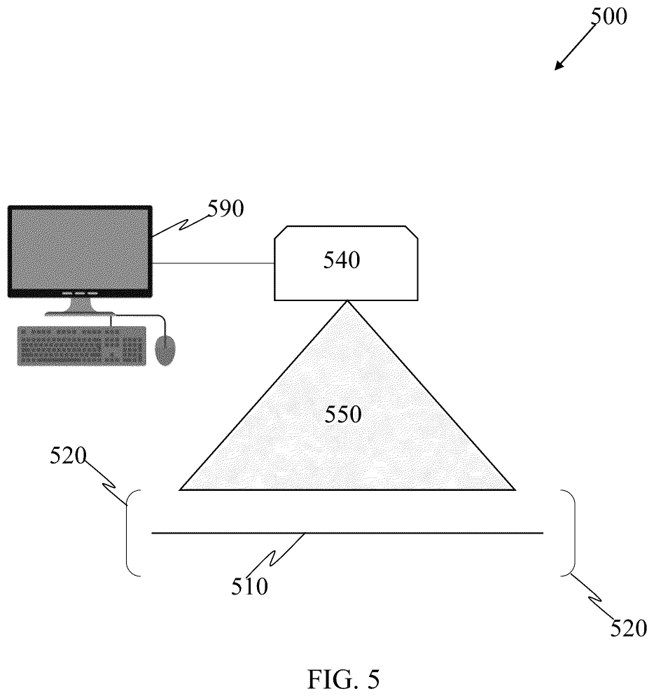

With reference to FIG. 5, according to various aspects, the system 500 may include an external computer 590 configured to provide instructions to the speaker 540 for emission of the sound waves 550. For example, the external computer 590 may include a non-transitory computer readable medium (not shown) that may provide instructions for the emission of sound waves 550 at the resonant frequency for the predetermined duration and at the predetermined amplitude to the membrane 510 assembled in the membrane holder 520.

In some aspects, the external computer 590 may be connected (with a cable or wireless) to the laser Doppler vibrometer (not shown). In such aspects, the laser Doppler vibrometer may communicate the displacement d that is measured for a respective frequency to the non-transitory computer readable medium of the external computer 590. There may be two purposes or uses of the laser Doppler vibrometer 380, 480: On one hand, the laser Doppler vibrometer 380, 480 may have the purpose of characterising the membrane material to extract the resonant frequency, and sound amplitude response. On the other hand, the laser Doppler vibrometer 380, 480 may have the purpose of providing feedback to the speaker 350, 450 to decrease volume when displacement d is equal or higher than the pre-determined threshold in order to prevent membrane damage or increase amplitude to improve cleaning efficiency if displacement d is lower than the set value. From a process efficiency perspective, it may be advantageous to keep the displacement d within a pre-set value by adjustment of the amplitude (e.g., volume).

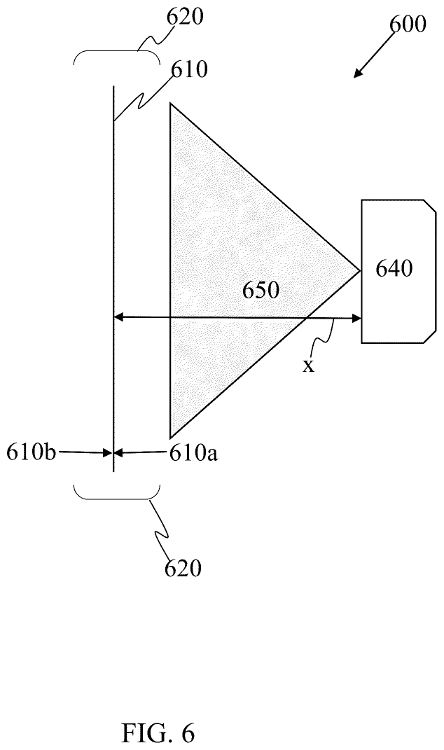

According to various aspects, as shown in FIG. 6, the speaker 640 may be positioned in a lateral arrangement from the membrane 610 in the membrane holder 620, such that emission of sound waves 650 is in a lateral direction. Advantageously, the spatial arrangement/orientation of the speaker 640 and membrane 610 can be reconfigured depending on the nature and size of the defects in question.

With respect to the difference in the arrangement of FIG. 1 and FIG. 6, in a horizontal arrangement as shown in FIG. 1, where the speaker 140 is on top of the membrane 110, the ejection of the particles from the opposing side of the membrane 110 may cause the particles to be influenced by gravity and to be ejected from the membrane 110 with less risk of re-contamination. Similarly, in vertical orientation as shown in FIG. 6, the process may take advantage of downward flow, (e.g. less risk of the particles to re-attach to another position on the membrane 610) while removing particles from both opposing sides 610a, 610b of the membrane 610, thereby improving throughput of the cleaning process.

In various aspects, there is provided a process 700 for cleaning a membrane. The process 700 may include providing the membrane and a membrane holder. The process 700 may include accommodating the membrane in a cut-out section within the membrane holder, wherein the cut-out section may allow access to the membrane from two opposing sides. The process 700 may include providing a speaker. The process 700 may include emitting sound waves of a resonant frequency, for a predetermined duration and at a predetermined amplitude from the speaker directed to one side of the membrane such that particles are ejected on the opposite side of the membrane.

The process 700 may also include the placement of the membrane from, e.g., a container into a membrane holder such that the cut-out section of the membrane holder provides access to the membrane. The membrane holder, together with the membrane may then be positioned to be in a distance x to the speaker. After the cleaning process 700, the membrane may be removed from the membrane holder and the membrane may either be returned to the container or may proceed to a subsequent process step. In some aspects, any of the preceding steps may be carried out manually or by a robot arm.

The process 700 may be carried out before the membrane is mounted on a reticle, i.e., the membrane undergoing the cleaning process may be substantially “free-standing”, only being supported by the membrane holder and optionally the membrane frame.

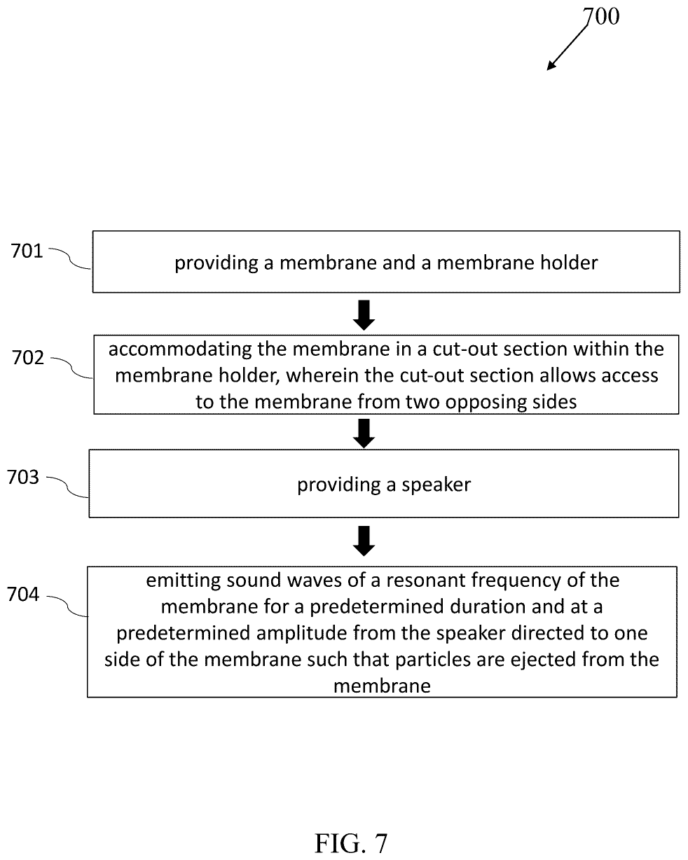

FIG. 7 shows a simplified flow diagram for an exemplary method according to an aspect of the present process 700.

The operation 701 may be directed to providing the membrane and a membrane holder.

The operation 702 may be directed to accommodating the membrane in a cut-out section within the membrane holder, wherein the cut-out section allows access to the membrane from two opposing sides.

The operation 703 may be directed providing a speaker.

The operation 704 may be directed to emitting sound waves of a resonant frequency, for a predetermined duration and at a predetermined amplitude from the speaker directed to one side of the membrane such that particles are ejected on the opposite side of the membrane.

According to various aspects, the emission of sound waves may be carried out applying a sweeping range, i.e. sweeping over a frequency range that includes repeating a particular frequency range, that includes the resonant frequency of the membrane. For example, applying the sweeping range may include starting at a frequency that is about 5 Hz below, or 10 Hz below the resonant frequency and stops at about 5 Hz above, or 10 Hz above the resonant frequency of the membrane. Alternatively, when the resonant frequency is at 254 Hz, e.g., then the sweeping range may be in the frequency range of about 200 Hz to about 300 Hz. Advantageously, when applying a sweeping range, it may be possible to expose the membrane to at least two of its resonant frequencies, thereby increasing the opportunity for ejection of particles from the membrane and improving the cleaning efficiency of the process. The sweeping range may be applied to the membrane multiple times, wherein a higher number of applying the sweeping range may provide better cleaning results.

According to various aspects, the speaker may be able to emit sound of two different frequencies simultaneously. Accordingly, the sound waves may be of at least two resonant frequencies. This can be achieved by either having multiple speakers or by multiple inputs to one speaker.

According to various aspects, the predetermined duration for carrying out the process 700 may be determined by a dwell time, defined as the length of time a certain frequency is applied to the membrane. This dwell time may be in the range of about 0.1 s to about 10000 s, or about 0.1 a to about 1000 s, or about 0.1 s to about 100 s, or about 0.1 s to about 10 s. In aspects where a sweeping range is applied to the membrane, the dwell time would be multiplied by each frequency that is applied to the membrane and the number of sweeping range cycles that are applied to the membrane. The total duration of the cleaning process is therefore defined as dwell time per frequency and sweeping range cycle. According to various aspects, the predetermined amplitude for carrying out the process 500 may be in the audible range, such as about 10 decibel (dB) to about 120 dB, or about 20 dB to about 100 dB, or about 30 dB to about 80 dB, or about 50 dB to about 70 dB. At a predetermined amplitude range of approximately 50 dB to 90 dB, the amplitude may be sufficiently high for ejection of the majority of the particles while being sufficiently low for not causing damage to the membrane within the membrane holder

The process 700 may further include a step of turning the membrane such that an opposite side would be exposed to the sound waves. For example, when in a first operation the side 110a (see, FIG. 1) faces the sound waves, and the particles are ejected from a side 110b, turning over the membrane such that side 110b faces the sound waves may ensure that the particles are then ejected from a side 110a. The turning of the membrane may be carried out manually or by robot arm.

The emission of sound waves at the resonant frequency of the membrane in the process 700 may require that said resonant frequency of the membrane is known (e.g., identified) before the cleaning process is carried out. Typically, membranes of the same type would have the same resonant frequencies, such that an identification process of said resonant frequency may only be required once prior to cleaning for each type and/or of membrane.

In other words, for each type of membrane for which the resonant frequency is not identified yet, the process 700 may further include an operation of identifying the resonant frequency of the membrane. This operation may include positioning a laser Doppler vibrometer (see, e.g., FIG. 3) into proximity of the membrane. Subsequently, the speaker may emit sound waves in of a considerable large frequency range, for example, about 1 Hz to about 2000 Hz, or of about 10 Hz to about 1000 Hz, or of about 50 Hz to about 500 Hz. The laser Doppler vibrometer may measure the displacement d of the membrane in response to each of these frequencies. The displacement d may be calculated from the measured velocity of the membrane vibration in time domain. The displacement d may be measured in reference to the membrane plane when it is not subjected to the sound wave. The displacement d at the resonant frequency may be several μm, such as more than 2 μm, or more than 5 μm, or between 1 μm to about 15 μm, or about 5 μm to about 12 μm.

In various aspects, the process 700 may be carried out in a particle-free environment surrounding the membrane, the membrane holder and the speaker.

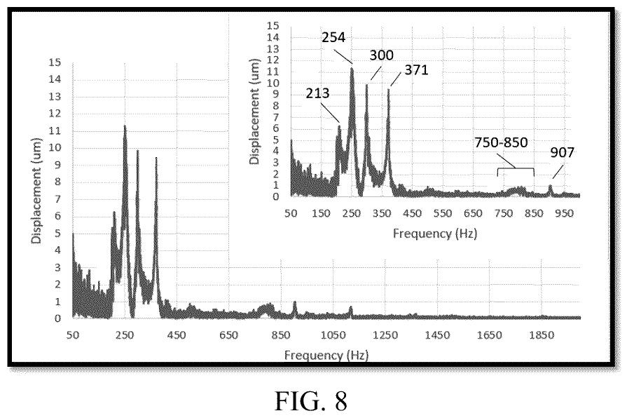

With reference to FIG. 8, in one example, the speaker emitted sound waves in the frequency range of 50 Hz to 2000 Hz and the exemplified membrane is a pellicle of the type Mk2.2. The resonant frequencies were identified at 213 Hz, 254 Hz, 300 Hz, and 371 Hz. Additional resonant frequencies were identified at 907 Hz and in 750-850 Hz range.

In another aspect, there is provided a non-transitory computer readable medium including instructions that, if executed, may cause one or more processors to emit sound waves through a speaker directed to a membrane at a resonant frequency of the membrane for a predetermined duration and at a predetermined amplitude. The membrane may be accommodated in a membrane holder.

According to various aspects, the non-transitory computer readable medium may include instructions to identify the resonant frequency of the membrane by emitting sound waves from the speaker directed to one side of the membrane in a frequency range of about 1 Hz to about 2000 Hz. Subsequently, the non-transitory computer readable medium may determine, based on the measured displacement d being higher than a predetermined threshold, the resonant frequency in the frequency range.

In a first example, there is provided a cleaning system including: a membrane; a membrane holder accommodating the membrane in a cut-out section within the membrane holder, wherein the cut-out section allows access to the membrane from two opposing sides; and a speaker configured to emit sound waves of a resonant frequency of the membrane for a predetermined duration and at a predetermined amplitude, wherein the sound waves are directed to one side of the membrane.

In a second example, the membrane of example 1 may be a pellicle configured to cover a photomask during photolithography.

In a third example, the speaker of example 1 and 2 may be positioned on top of the membrane configured to emit the sound waves from an upper position towards the membrane.

In a fourth example, the speaker of any one of examples 1 to 3 may be positioned at a distance of approximately 10 mm to 20 mm to the membrane.

In a fifth example, the membrane holder of any one of examples 1 to 4 may span about 10 mm to about 20 mm at its shortest dimension.

In a sixth example, the membrane holder of any one of examples 1 to 5 may further include a membrane frame configured to hold the membrane within the membrane holder.

In a seventh example, the system any one of examples 1 to 6 may include a laser Doppler vibrometer configured to measure a displacement of the membrane within the membrane holder, wherein the displacement is compared with a predetermined threshold.

In an eighth example, the system of any one of examples 1 to 7 may further include a computer with a non-transitory computer readable medium including instructions which, if executed by a processor, cause the processor to control the speaker to emit sound waves of the resonant frequency of the membrane, for the predetermined duration and at the predetermined amplitude.

In a ninth example, the speaker of any one of examples 1 to 8 may be positioned on a side of the membrane configured to emit the sound waves from a lateral position towards the membrane.

In a tenth example, the photomask of example 2 may be used for extreme ultraviolet photolithography.

In an eleventh example, there is provided a membrane cleaning process including: providing a membrane and a membrane holder; accommodating the membrane in a cut-out section within the membrane holder, wherein the cut-out section allows access to the membrane from two opposing sides; providing a speaker; and emitting sound waves of a resonant frequency, for a predetermined duration and at a predetermined amplitude from the speaker directed to one side of the membrane such that particles are ejected from the membrane.

In a twelfth example, the process of the example 11 may further include emitting sound waves in a sweeping range including the resonant frequency of the membrane.

In a thirteenth example, the predetermined amplitude of the emitted sound waves of the example 11 or 12 may be in the range of approximately 50 decibel to 90 decibel.

In a fourteenth example, the predetermined duration of the emitted sound waves of any one of examples 11 to 13 may be in the range of approximately 1 millisecond to 10000 milliseconds.

In a fifteenth example, the process of any one of examples 11 to 14 may include positioning the speaker on top of the membrane to emit the sound waves from an upper position towards the membrane.

In a sixteenth example, the process of any one of examples 11 to 15 may include turning over the membrane holder together with the membrane to have an opposite side of the membrane face the speaker and repeating the emission of sound waves at the resonant frequency for the membrane, for the predetermined duration and at the predetermined amplitude.

In a seventeenth example, the process of any one of examples 11 to 16 may include identification of the resonant frequency of the membrane by emitting sound waves from the speaker directed to one side of the membrane in a frequency range of approximately 1 Hz to 2000 Hz and determining the resonant frequency in the frequency range that corresponds to a displacement of the membrane that is above a predetermined threshold.

In an eighteenth example, the displacement of the membrane of the example 17 may be determined with a laser Doppler vibrometer.

In a nineteenth example, there is provided a non-transitory computer readable medium including instructions that, if executed, may cause one or more processors to control a speaker to emit sound waves directed to a membrane that is accommodated in a membrane holder at a resonant frequency of the membrane for a predetermined duration and at a predetermined amplitude.

In a twentieth example, the non-transitory computer readable medium of example 19 may include identification of the resonant frequency of the membrane by emitting sound waves from the speaker directed to one side of the membrane at a frequency range of approximately 1 Hz to 2000 Hz and determining the resonant frequency in the frequency range that corresponds to a displacement of the membrane that is above a predetermined threshold.

The properties of the system and the process presented above are intended to be exemplary for the membranes. It will be apparent to those ordinary skilled practitioners that the foregoing process operations may be modified without departing from the spirit of the present disclosure.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

By “about” or “approximately” in relation to a given numerical value, such as for amplitude, duration, frequency, thickness and height, it is meant to include numerical values within 10% of the specified value.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

1. A membrane cleaning system comprising:
a membrane;
a membrane holder accommodating the membrane in a cut-out section within the membrane holder, wherein the cut-out section allows access to the membrane from two opposing sides; and
a speaker configured to emit sound waves of a resonant frequency of the membrane for a predetermined duration and at a predetermined amplitude, wherein the sound waves are directed to one side of the membrane.

2. The membrane cleaning system of claim 1, wherein the membrane is a pellicle configured to cover a photomask during photolithography.

3. The membrane cleaning system of claim 1, wherein the speaker is positioned on top of the membrane configured to emit the sound waves from an upper position towards the membrane.

4. The membrane cleaning system of claim 1, wherein the speaker is positioned at a distance of approximately 10 mm to 20 mm to the membrane.

5. The membrane cleaning system of claim 1, wherein the membrane holder spans about 10 mm to about 20 mm at its shortest dimension.

6. The membrane cleaning system of claim 1, the membrane holder further comprising a membrane frame configured to hold the membrane within the membrane holder.

7. The membrane cleaning system of claim 1, further comprising a laser Doppler vibrometer configured to measure a displacement of the membrane within the membrane holder, wherein the displacement is compared with a predetermined threshold.

8. The membrane cleaning system of claim 1, further comprising a computer with a non-transitory computer readable medium comprising instructions which, if executed by a processor, cause the processor to control the speaker to emit sound waves of the resonant frequency of the membrane, for the predetermined duration and at the predetermined amplitude.

9. The membrane cleaning system of claim 1, wherein the speaker is positioned on a side of the membrane configured to emit the sound waves from a lateral position towards the membrane.

10. The membrane cleaning system of claim 2, wherein the photomask is used for extreme ultraviolet photolithography.

11. A membrane cleaning process comprising:
providing a membrane and a membrane holder;
accommodating the membrane in a cut-out section within the membrane holder, wherein the cut-out section allows access to the membrane from two opposing sides;
providing a speaker; and
emitting sound waves of a resonant frequency of the membrane for a predetermined duration and at a predetermined amplitude from the speaker directed to one side of the membrane such that particles are ejected from the membrane.

12. The membrane cleaning process of claim 11, further comprising emitting sound waves in a sweeping range comprising the resonant frequency of the membrane.

13. The membrane cleaning process of claim 11, wherein the predetermined amplitude of the emitted sound waves is in the range of approximately 50 decibel to 90 decibel.

14. The membrane cleaning process of claim 11, wherein the predetermined duration of the emitted sound waves is in the range of approximately 1 milliseconds to 10000 milliseconds.

15. The membrane cleaning process of claim 11, further comprising positioning the speaker on top of the membrane to emit the sound waves from an upper position towards the membrane.

16. The membrane cleaning process of claim 11, further comprising turning over the membrane holder together with the membrane to have an opposite side of the membrane face the speaker and repeating the emission of sound waves at the resonant frequency for the membrane, for the predetermined duration and at the predetermined amplitude.

17. The membrane cleaning process of claim 11, further comprising identification of the resonant frequency of the membrane by emitting sound waves from the speaker directed to one side of the membrane in a frequency range of approximately 1 Hz to 2000 Hz and determining the resonant frequency in the frequency range that corresponds to a displacement of the membrane that is above a predetermined threshold.

18. The membrane cleaning process of claim 17, wherein the displacement of the membrane is determined with a laser Doppler vibrometer.

19. A non-transitory computer readable medium comprising instructions that, if executed, cause one or more processors control a speaker to emit sound waves directed to a membrane that is accommodated in a membrane holder at a resonant frequency of the membrane for a predetermined duration and at a predetermined amplitude.

20. The non-transitory computer readable medium of claim 19, further comprising identification of the resonant frequency of the membrane by emitting sound waves from the speaker directed to one side of the membrane at a frequency range of approximately 1 Hz to 2000 Hz and determining the resonant frequency in the frequency range that corresponds to a displacement of the membrane that is above a predetermined threshold.
